(19) United States
(12) Patent Application Publication
(10) Pub. No.: US 2024/0377448 A1
(43) Pub. Date: Nov. 14, 2024

(54) APPARATUS, SYSTEM, AND METHOD OF DETERMINING ELECTRICAL MELTING TRACES BY DIRECT CURRENT AND ALTERNATING CURRENT IN WIRES BASED ON DEEP LEARINING

(71) Applicant: REPUBLIC OF KOREA (NATIONAL FORENSIC SERVICE DIRECTOR MINISTRY OF THE INTERIOR AND SAFETY), Wonju-si (KR)

(72) Inventors: Kyu Young LIM, Wonju-si (KR); Young Il SEO, Wonju-si (KR); Byung Seon MOON, Busan (KR); Jin Pyo KIM, Daejeon (KR)

(21) Appl. No.: 18/227,063

(22) Filed: Jul. 27, 2023

(30) Foreign Application Priority Data
May 10, 2023 (KR) 10-2023-0060572

(51) Int. Cl. G01R 31/08; G01R 31/52; G01R 31/54

(52) U.S. Cl. CPC G01R 31/083; G01R 31/088; G01R 31/52; G01R 31/54; G06T 7/0004

(57) ABSTRACT

An apparatus for determining electrical melting traces by direct current and alternating current in wires based on deep learning includes an image obtaining unit configured to obtain a wire image including an electrical melting trace, a trained model application unit configured to calculate a probability (determination probability) of determining the electrical melting trace as an electrical melting trace by direct current or alternating current by applying a pre-trained model, and a determination unit configured to determine the electrical melting trace according to a set determination condition.

### CROSS-REFERENCE TO RELATED APPLICATIONS

The present application is based on and claims priority to Korean Patent Application No. 10-2023-0060572 filed on May 10, 2023, in the Korean Intellectual Property Office, which is incorporated herein by reference in its entirety.

### BACKGROUND

### 1. Field

One or more embodiments relate to apparatus, system, and method of determining electrical melting traces by direct current and alternating current in wires based on deep learning.

### 2. Description of the Related Art

In investigating the causes of fire, explosion, arson and crime, whether or not an electrical melting trace is found is a very important clue in determining the possibility of ignition by electrical causes. This is because an electrical melting trace may be formed by igniting adjacent combustibles using electrical heat or sparks generated at the site as an ignition source.

Electrical melting traces often appear on a wire. Electrical melting traces only occur when a wire is energized. At this time, a current flowing through the wire may be direct current or alternating current.

In actual fires, explosions, arson and crimes, wires are exposed to flames, or wires are often fragmented in the process of forming electrical melting traces or extinguishing fires. When a wire is fragmented, it is difficult to check a wiring relationship, so it is difficult to determine whether an electrical melting trace of the wire is due to direct current or alternating current.

One of the methods of generating direct current is a method of converting alternating current into direct current through a power conversion process.

For example, in a case of an electronic product, wires through which direct current is conducted are wires inside the electronic product. Accordingly, when electrical melting traces by direct current are identified in wires found in certain electronic products, a possibility that the electrical melting traces are formed by problems inside the product may be considered.

Electrical melting traces formed on wires have a difference in external form depending on whether conducting current is direct current or alternating current. In general, an electrical melting trace by direct current often has an elongated melting portion, and an electrical melting trace by alternating current often has a short melting portion.

### SUMMARY

One or more embodiments include an apparatus and method capable of determining whether an electrical melting trace formed on a wire is due to direct current or alternating current according to the type of conducting current by utilizing a convolutional neural network (CNN) from among deep learning techniques.

One or more embodiments include an apparatus and method capable of more clearly identifying the cause of a fire by determining whether an electrical melting trace formed on a wire is due to direct current or alternating current.

According to one or more embodiments, an apparatus for determining electrical melting traces by direct current and alternating current in wires based on deep learning includes an image obtaining unit configured to obtain a wire image including an electrical melting trace, a trained model application unit configured to calculate a probability (determination probability) of determining the electrical melting trace as an electrical melting trace by direct current or alternating current by applying a pre-trained model, and a determination unit configured to determine the electrical melting trace according to a set determination condition.

In an embodiment, the set determination condition may determine an electrical melting trace having a higher determination probability and greater than or equal to a reference value from among electrical melting traces by direct current or alternating current.

In an embodiment, the apparatus for determining electrical melting traces by direct current and alternating current in wires based on deep learning may further include a trained model generation unit configured to generate the pre-trained model by using wire images including electrical melting traces by direct current and alternating current used in an appraisal report as training data.

In an embodiment, the pre-trained model may be a convolutional neural network (CNN)-based deep learning model.

According to one or more embodiments, a system for determining electrical melting traces by direct current and alternating current in wires based on deep learning includes an apparatus for determining electrical melting traces by direct current and alternating current in wires based on deep learning configured to obtain a wire image including an electrical melting trace and to determine the electrical melting trace included in the wire image as an electrical melting trace by direct current or alternating current by applying a pre-trained model, and a server configured to receive user input text information related to an electrical melting trace in the wire and to provide a wire image including the electrical melting trace based on the user input text information.

According to one or more embodiments, a method of determining electrical melting traces by direct current and alternating current in wires based on deep learning includes obtaining a wire image including an electrical melting trace, calculating a probability (determination probability) of determining the electrical melting trace as an electrical melting trace by direct current or alternating current by applying a pre-trained model, and determining the electrical melting trace according to a set determination condition.

In an embodiment, the method of determining electrical melting traces by direct current and alternating current in wires based on deep learning may further include generating the pre-trained model by using wire images including electrical melting traces by direct current and alternating current used in an appraisal report as training data.

In an embodiment, the generating of the pre-trained model may include obtaining wire images including electrical melting traces by direct current and alternating current used in an appraisal report, and generating a CNN-based deep learning model by using the wire images including electrical melting traces by direct current and alternating current as training data.

In an embodiment, the obtaining of wire images including electrical melting traces by direct current and alternating current used in the appraisal report may include obtaining user input text information related to electrical melting traces by direct current and alternating current, and receiving, by a server, the user input text information and providing wire images including electrical melting traces by direct current and alternating current based on the user input text information.

Additional aspects will be set forth in part in the description which follows and, in part, will be apparent from the description, or may be learned by practice of the embodiments.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic block diagram of a system and apparatus for determining electrical melting traces by direct current and alternating current in wires based on deep learning, according to an embodiment;

FIG. 2 is a view showing electrical melting traces by direct current and alternating current of wires by way of example;

FIG. 3 is a flowchart illustrating a method of determining electrical melting traces by direct current and alternating current in wires based on deep learning, according to an embodiment;

FIG. 4 is a flowchart illustrating generating a pre-trained model according to an embodiment;

FIG. 5 is a view illustrating an operation according to a system for determining electrical melting traces by direct current and alternating current in wires based on deep learning, according to an embodiment;

FIG. 6 is a view of a wire image including an electrical melting trace by direct current; and

FIG. 7 is a view of a wire image including an electrical melting trace by alternating current.

### DETAILED DESCRIPTION

Hereinafter, embodiments will be described in detail with reference to the accompanying drawings. The same reference numerals are used to denote the same elements, and repeated descriptions thereof will be omitted. It will be understood that although the terms “first,” “second,” etc. may be used herein to describe various elements, these elements should not be limited by these terms.

An expression used in the singular encompasses the expression of the plural, unless it has a clearly different meaning in the context. It will be further understood that the terms “comprises” and/or “comprising” used herein specify the presence of stated features or components, but do not preclude the presence or addition of one or more other features or components.

Sizes of elements in the drawings may be exaggerated for convenience of explanation. In other words, since sizes and thicknesses of components in the drawings are arbitrarily illustrated for convenience of description, the following embodiments are not limited thereto. When a certain embodiment may be implemented differently, a specific process order may be performed differently from the described order. For example, two consecutively described processes may be performed substantially at the same time or performed in an order opposite to the described order.

In this specification, a ‘wire’ is an electrical conductor used to transmit current from one point to another. The ‘wire’ is usually made of a metal or alloy with low electrical resistance, such as copper. The ‘wire’ is insulated with a non-conductive material, such as plastic or rubber, to prevent electric shock and prevent damage. The ‘wire’ is used for various purposes such as power transmission and distribution, communication, and electronic devices.

In this specification, ‘direct current’ is current that flows in one direction in a circuit, and ‘alternating current’ is current that periodically changes the direction of flow. The ‘direct current’ may be used in batteries, electronic circuits and certain types of motors, etc., and the ‘alternating current’ may be used in various electrical systems because it has less energy loss than direct current and can be transmitted over long distances.

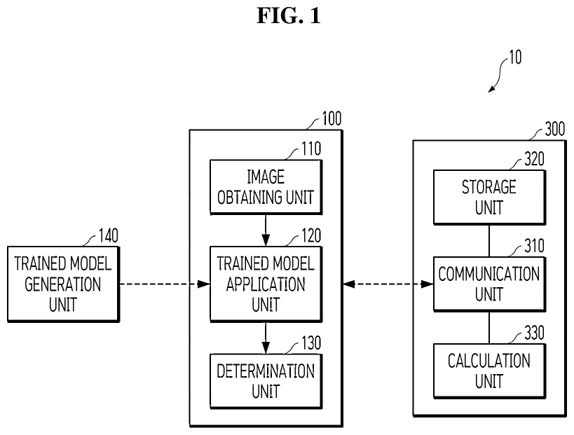

FIG. 1 is a schematic block diagram of a system and apparatus for determining electrical melting traces by direct current and alternating current in wires based on deep learning, according to an embodiment.

Referring to FIG. 1, a system 10 for determining electrical melting traces by direct current and alternating current in wires based on deep learning according to an embodiment may include an apparatus 100 for determining electrical melting traces by direct current and alternating current in wires based on deep learning, and a server 300.

The system 10 for determining electrical melting traces by direct current and alternating current in wires based on deep learning according to an embodiment, after generating a pre-trained model by collecting a large amount of wire images photographed at an actual fire site and used for an appraisal report, may determine whether an electrical melting trace in wire images including electrical melting traces obtained at a fire site is an electrical melting trace by direct current or an electrical melting trace by alternating current.

The apparatus 100 for determining electrical melting traces by direct current and alternating current in wires based on deep learning according to an embodiment may be an apparatus that determines whether an electrical melting trace of a wire in a wire image obtained at a fire site is due to direct current or alternating current, and displays the result.

The apparatus 100 for determining electrical melting traces by direct current and alternating current in wires based on deep learning may be various types of information processing devices used by users. For example, the apparatus 100 for determining electrical melting traces by direct current and alternating current in wires based on deep learning may be a personal computer (PC), a laptop computer, a mobile phone, a tablet PC, a smart phone, or a personal digital assistant (PDA). The apparatus 100 for determining electrical melting traces by direct current and alternating current in wires based on deep learning may be borrowed without limitation as long as an application for which a method 200 of determining electrical melting traces by direct current and alternating current in wires based on deep learning provided by an embodiment is programmed can be loaded.

The apparatus 100 for determining electrical melting traces by direct current and alternating current in wires based on deep learning shown in FIG. 1 shows only components related to the present embodiment in order to prevent features of the present embodiment is blurred.

The apparatus 100 for determining electrical melting traces by direct current and alternating current in wires based on deep learning according to an embodiment may include an image obtaining unit 110, a trained model application unit 120, and a determination unit 130.

The image obtaining unit 110 may obtain a wire image including an electrical melting trace.

As an embodiment, the image obtaining unit 110 may obtain a wire image including an electrical melting trace found at a fire site.

The image obtaining unit 110 may obtain an image by directly photographing a wire including an electrical melting trace. In addition, the image obtaining unit 110 may receive an image from another photographing device (microscope, camera, etc.) or the server 300.

The trained model application unit 120 may calculate a probability (determination probability) of determining an electrical melting trace as an electrical melting trace by direct current or alternating current by applying a pre-trained model.

The pre-trained model applied here may be a convolutional neural network (CNN)-based deep learning model (CNN model). The CNN model recognizes unique patterns of images and classify the images based on the unique patterns. For example, in more detail, the CNN model may be any one of ALEXNET, ZFNET, VGGNET, GOOGLENET, RESNET, WIDE RESNET, VGG19, INCEPTION V3, INCEPTION V4, XCEPTION, SQUEEZENET, DENSENET, and MOBILENETS.

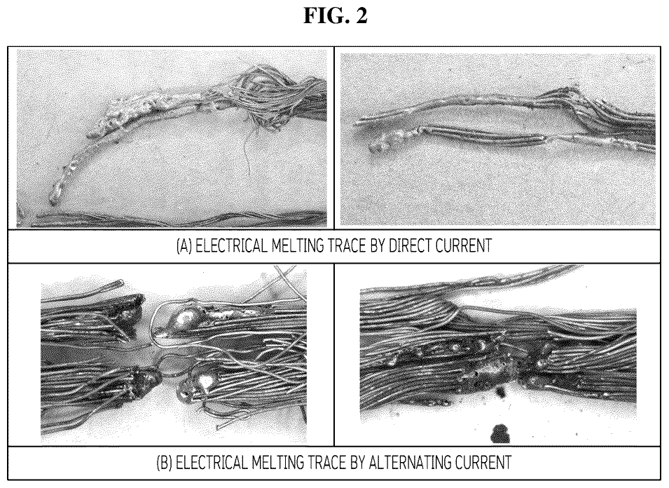

FIG. 2 is a view showing electrical melting traces by direct current and alternating current of wires by way of example. Referring to FIG. 2, a wire image including an electrical melting trace by direct current and a wire image including an electrical melting trace by alternating current are visually different in the length of a melting portion.

For example, the trained model application unit 120 may calculate a determination probability of 68.10% of electrical melting traces by direct current and 31.90% of electrical melting traces by alternating current in wire images including electrical melting traces.

The determination unit 130 may determine an electrical melting trace according to a set determination condition.

In more detail, the determination unit 130 may determine an electrical melting trace as an electrical melting trace that satisfies a set determination condition. In addition, the determination unit 130 may determine that the electrical melting trace is ‘indeterminable’ when the electrical melting trace does not satisfy the set determination condition.

The electrical melting trace that satisfies the set determination condition may be an electrical melting trace having a higher determination probability and greater than or equal to a reference value from among electrical melting traces by direct current or alternating current.

Accordingly, the determining unit 130 may determine an electrical melting trace of a wire as either an electrical melting trace by direct current or alternating current. The determination unit 130 may determine that the electrical melting trace is ‘indeterminable’ when the electrical melting trace does not satisfy the set determination condition.

For example, when a reference probability is 70.00% or more and a determination probability of an electrical melting trace by direct current is 75.00%, the determination unit 130 may determine the electrical melting trace as an ‘electrical melting trace by direct current’. In addition, when a determination probability of an electrical melting trace by direct current is 55.00% and a determination probability of an electrical melting trace by alternating current is 45.00%, a determination probability of an electrical melting trace by direct current with a higher value is not more than a value of a reference probability, and thus the determination unit 130 may determine that the electrical melting trace is ‘indeterminable’.

In addition, the apparatus 100 for determining electrical melting traces by direct current and alternating current in wires based on deep learning according to an embodiment may further include a trained model generation unit 140.

The trained model generation unit 140 may generate a pre-trained model by using wire images including electrical melting traces by direct current and alternating current used in an appraisal report as training data. The appraisal report refers to a document that describes an appraisal process and its results based on the expert knowledge and experience of an appraiser. The appraisal report may include images of electrical melting traces found at fire, explosion, or arson sites, so wire images included in the appraisal report may be used to generate a pre-trained model.

The trained model generation unit 140 may be included in the apparatus 100 for determining electrical melting traces by direct current and alternating current in wires based on deep learning, or may be included in a separate external device.

Referring to FIG. 1, the system 10 for determining electrical melting traces by direct current and alternating current in wires based on deep learning may further include the server 300.

As an embodiment, the server 300 may include a communication unit 310, a storage unit 320, and a calculation unit 330.

The communication unit 310 is a portion through which the server 300 communicates with the apparatus 100 for determining electrical melting traces by direct current and alternating current in wires based on deep learning and other devices outside the server 300, and a communication method is not particularly limited. For example, the communication unit 310 may use various wired and wireless communication methods including short-range wireless communication such as WiFi, Bluetooth, and NFC.

The storage unit 320 may store a wire image including an electrical melting trace. In addition, the storage unit 320 may store appraisal report data including wire images found at fire, explosion, or arson sites.

The calculation unit 330 may obtain user input text information related to an electrical melting trace in a wire from the apparatus 100 for determining electrical melting traces by direct current and alternating current in wires based on deep learning, and may provide a wire image including an electrical melting trace stored in the storage unit 320 based on the user input text information.

For example, the calculation unit 330 may receive an input signal related to a specific word by a user of the apparatus 100 for determining electrical melting traces by direct current and alternating current in wires based on deep learning, and may search for and provide an appraisal report including an image corresponding to a combination of related words from among appraisal reports stored in the storage unit 320.

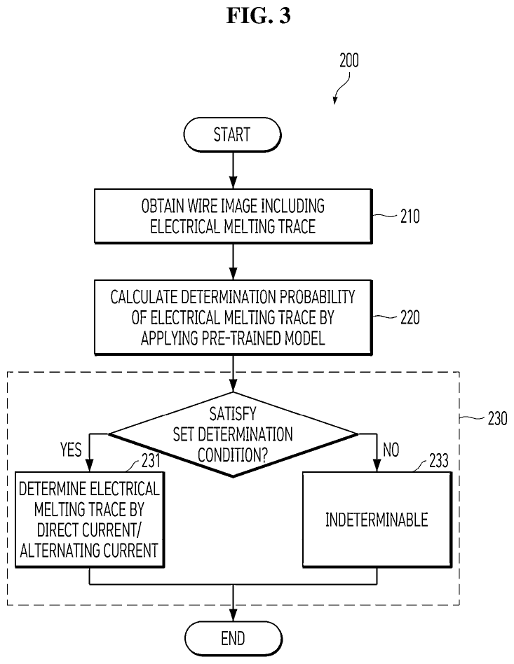

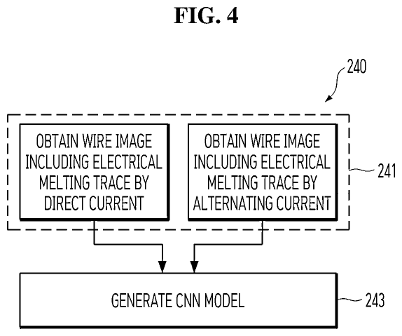

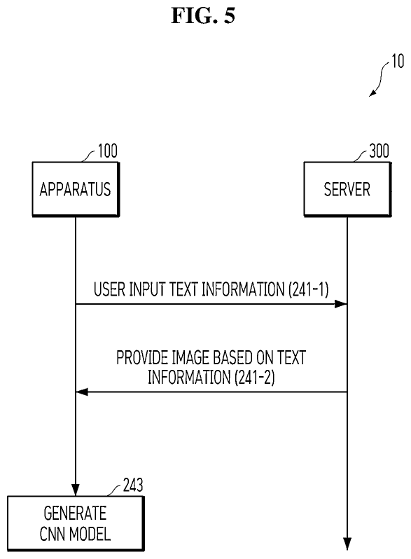

FIG. 3 is a flowchart illustrating a method of determining electrical melting traces by direct current and alternating current in wires based on deep learning, according to an embodiment. FIG. 4 is a flowchart illustrating generating a pre-trained model according to an embodiment. FIG. 5 is a view illustrating an operation according to a system for determining electrical melting traces by direct current and alternating current in wires based on deep learning, according to an embodiment.

Referring to FIGS. 3 to 5, a method 200 of determining electrical melting traces by direct current and alternating current in wires based on deep learning according to an embodiment will be described. For convenience of description, the content overlapping with the apparatus 100 for determining electrical melting traces by direct current and alternating current in wires based on deep learning will be omitted or simplified.

Operation 210 is obtaining a wire image including an electrical melting trace.

Operation 210 may be performed by the image obtaining unit 110.

For example, the image obtaining unit 110 may obtain a wire image found at a fire site by photographing a wire found at a fire site with a camera or a microscope.

Operation 220 is calculating a probability (determination probability) of determining an electrical melting trace as an electrical melting trace by direct current or alternating current by applying a pre-trained model.

Operation 220 may be performed by the trained model application unit 120.

Operation 230 is determining the electrical melting trace according to a set determination condition.

Operation 230 may be performed by the determination unit 130.

In more detail, in operation 230, the determination unit 130 determines the electrical melting trace as an electrical melting trace that satisfies the set determination condition (operation 231), and when the electrical melting trace does not satisfy the set determination condition, the determination unit 130 determines that the electrical melting trace is ‘indeterminable’ (operation 233).

The method 200 of determining electrical melting traces by direct current and alternating current in wires based on deep learning according to an embodiment may further include operation 240 of generating a pre-trained model.

In more detail, operation 240 is generating a pre-trained model by using wire images including electrical melting traces by direct current and alternating current used in an appraisal report as training data.

Operation 240 may be performed by the trained model generation unit 140.

Operation 240 may include operations 241 and 243.

Operation 241 is obtaining wire images including electrical melting traces by direct current and alternating current used in the appraisal report.

In more detail, in operation 241-1, the apparatus 100 for determining electrical melting traces by direct current and alternating current in wires based on deep learning obtains user input text information related to electrical melting traces by direct current and alternating current. In operation 241-2, the server 300 receives the user input text information and provides wire images including electrical melting traces by direct current or alternating current based on the user input text information.

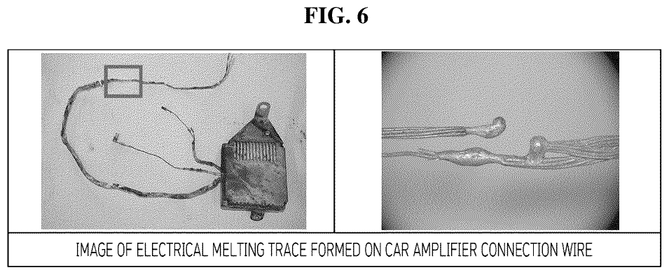

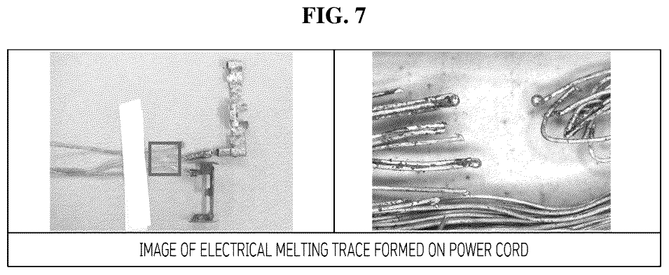

FIGS. 6 and 7 are views of wire images including electrical melting traces by direct current and alternating current, respectively.

For example, images including electrical melting traces as shown in FIGS. 6 and 7 can be collected as follows.

In the case of a wire image including an electrical melting trace by direct current, a user of the apparatus 100 for determining electrical melting traces by direct current and alternating current in wires based on deep learning may input two words, ‘vehicle’ and ‘short circuit mark’. The server 300 may receive an input signal and provide an image corresponding to a combination of the two words input by the user. The server 300 may provide an appraisal report including an image of a ‘vehicle’ including a ‘short circuit mark’ from among stored appraisal reports.

As shown in FIG. 6, the wire image including an electrical melting trace by direct current may be a wire image found in automobiles (cars, trucks, agricultural machinery, electric carts, etc.), motorcycles, and the like, which are machines using batteries.

In the case of a wire image including an electrical melting trace by alternating current, a user may be provided with an appraisal report including a wire image of a ‘power cord’ including a ‘short circuit mark’ from the server 300 using words ‘power cord’ and ‘short circuit mark’.

As shown in FIG. 7, the wire image including an electrical melting trace by alternating current may be an image of an electrical melting trace left on a power cord connected to an AC outlet.

Operation 243 is generating a CNN-based deep learning model (CNN model) by using wire images including electrical melting traces by direct current and alternating current as training data.

According to embodiments, by using a CNN from among deep learning techniques, it is possible to determine whether an electrical melting trace formed on a wire is due to direct current or alternating current according to the type of conducting current, and thus determination accuracy of electrical melting traces may be improved.

According to embodiments, it is possible to more clearly identify the cause of a fire by determining whether an electrical melting trace formed on a wire is due to direct current or alternating current.

The method 200 of determining electrical melting traces by direct current and alternating current in wires based on deep learning according to an embodiment shown in FIG. 3 may be written as computer programs and may be implemented in general-use digital computers that execute the programs using a non-transitory computer-readable recording medium. The non-transitory computer-readable recording medium may be a magnetic storage medium (e.g., ROM, a floppy disk, a hard disk, etc.), or an optical reading medium (e.g., a CD-ROM, a digital versatile disk (DVD) or the like).

It should be understood that embodiments described herein should be considered in a descriptive sense only and not for purposes of limitation. Descriptions of features or aspects within each embodiment should typically be considered as available for other similar features or aspects in other embodiments. Therefore, the scope of the disclosure is defined by the appended claims.

What is claimed is:

1. An apparatus for determining electrical melting traces by direct current and alternating current in wires based on deep learning, the apparatus comprising:
an image obtaining unit configured to obtain a wire image including an electrical melting trace;
a trained model application unit configured to calculate a probability (determination probability) of determining the electrical melting trace as an electrical melting trace by direct current or alternating current by applying a pre-trained model; and
a determination unit configured to determine the electrical melting trace according to a set determination condition.

2. The apparatus of claim 1, wherein the set determination condition determines an electrical melting trace having a higher determination probability and greater than or equal to a reference value from among electrical melting traces by direct current or alternating current.

3. The apparatus of claim 1, further comprising:
a trained model generation unit configured to generate the pre-trained model by using wire images including electrical melting traces by direct current and alternating current used in an appraisal report as training data.

4. The apparatus of claim 1, wherein the pre-trained model is a convolutional neural network (CNN)-based deep learning model.

5. A system for determining electrical melting traces by direct current and alternating current in wires based on deep learning, the system comprising:
an apparatus for determining electrical melting traces by direct current and alternating current in wires based on deep learning configured to obtain a wire image including an electrical melting trace and to determine the electrical melting trace included in the wire image as an electrical melting trace by direct current or alternating current by applying a pre-trained model; and
a server configured to receive user input text information related to an electrical melting trace in the wire and to provide a wire image including the electrical melting trace based on the user input text information.

6. A method of determining electrical melting traces by direct current and alternating current in wires based on deep learning, the method comprising:
obtaining a wire image including an electrical melting trace;
calculating a probability (determination probability) of determining the electrical melting trace as an electrical melting trace by direct current or alternating current by applying a pre-trained model; and
determining the electrical melting trace according to a set determination condition.

7. The method of claim 6, further comprising:
generating the pre-trained model by using wire images including electrical melting traces by direct current and alternating current used in an appraisal report as training data.

8. The method of claim 7, wherein the generating of the pre-trained model comprises:
obtaining wire images including electrical melting traces by direct current and alternating current used in an appraisal report; and
generating a CNN-based deep learning model by using the wire images including electrical melting traces by direct current and alternating current as training data.

9. The method of claim 8, wherein the obtaining of wire images including electrical melting traces by direct current and alternating current used in the appraisal report comprises:
obtaining user input text information related to electrical melting traces by direct current and alternating current; and
receiving, by a server, the user input text information and providing wire images including electrical melting traces by direct current and alternating current based on the user input text information.
